(19) United States
(12) Patent Application Publication
(10) Pub. No.: US 2002/0153554 A1
(43) Pub. Date: Oct. 24, 2002

(54) Semiconductor device having a capacitor and manufacturing method thereof

(76) Inventors: Akihiro Kajita, Yokohama-shi (JP); Masaki Yamada, Yokohama-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/126,545

(22) Filed: Apr. 22, 2002

(30) Foreign Application Priority Data
Apr. 23, 2001 (JP) 2001-123873

(51) Int. Cl. H01L 31/119; H01L 29/94; H01L 29/76; H01L 27/108

(52) U.S. Cl. 257/306

(57) ABSTRACT

An MIM-type capacitor has a lower electrode film, a capacitor insulation film and an upper electrode film. An upper electrode wiring is in direct contact with the upper electrode film. A second wiring layer is connected to a first wiring layer through a wiring plug. A lower electrode wiring is connected to the lower electrode film through a lower electrode plug.

### CROSS-REFERENCE TO RELATED APPLICATIONS

This application is based upon and claims the benefit of priority from the prior Japanese Patent Application No. 2001-123873, filed Apr. 23, 2001, the entire contents of which are incorporated herein by reference.

### BACKGROUND OF THE INVENTION

1. Field of the Invention

The present invention relates to a semiconductor device having a capacitor mounted therein and more particularly to a semiconductor device in which analog and digital circuits are merged and a method of manufacturing the same.

2. Description of the Related Art

Recently, system large scale integrated circuits (LSIs) in which some LSIs are merged have been used with intensified compactness and increased speed. Further, communication technology has developed more rapidly than expected. Analog/digital merged-type LSIs in which an analog circuit and a digital circuit are merged in an LSI for use in such communication have been developed by a number of companies.

A high precision capacitor which has a stable characteristic not dependent on voltage is needed to construct such an analog circuit. As this capacitor, a polysilicon insulator polysilicon (PIP) type capacitor has been utilized. In this PIP-type capacitor, an ONO film is sandwiched between a poly-Si electrode in which an impurity is doped and another poly-Si electrode.

However, because the voltage coefficient and temperature coefficient of the PIP-type capacitor are high, it has dependency upon voltage and temperature. Further, the PIP-type capacitor has such a problem that the LSI cannot execute a stable operation because the resistance of the Poly-Si is large.

Then, public attention has been paid to a metal insulator metal (MIM) type capacitor so as to overcome these problems. This MIM-type capacitor uses a metal having a lower voltage coefficient and electrical resistance than the Poly-Si. Further, because this MIM-type capacitor is formed in a multi-layered wiring layer, its parasitic capacitance can be suppressed.

FIGS. 7A to 7I show a configuration of an MIM capacitor and manufacturing process thereof.

As shown in FIG. 7A, a first interlayer insulation film 103 is formed on a semiconductor substrate 101 through an insulation film 102. A first wiring layer 106 is formed in the first interlayer insulation film 103. This first wiring layer 106 is comprised of a wiring 105 and a barrier metal film 104. A barrier film 107 is formed on the first interlayer insulation film 103 and the first wiring layer 106 so as to prevent diffusion and oxidation. This barrier film 107 is made of insulator, for example, SiN.

As shown in FIG. 7B, a lower electrode metal 108, a dielectric film 109 and an upper electrode metal 110 are deposited in order on the barrier film 107.

As shown in FIG. 7C, a resist pattern (not shown) is formed on the upper electrode metal 110 and with the aforementioned resist pattern as a mask, the upper electrode metal 110 and the dielectric film 109 are etched. After this, the resist pattern is removed by ashing. As a result, an upper electrode film 110a and a capacitor insulation film 109a are formed.

Next, as shown in FIG. 7D, a resist pattern (not shown) is formed on the upper electrode film 110a and the lower electrode metal 108 and then, with this resist pattern as a mask, the lower electrode metal 108 is etched. After this, the resist pattern is removed by ashing. Consequently, an MIM-type capacitor 111 comprised of the lower electrode film 108a, the capacitor insulation film 109a and the upper electrode film 110a is formed.

Next as shown in FIG. 7E, a second interlayer insulation film 112 is deposited on the first interlayer insulation film 103.

Next, as shown in FIG. 7F, the second interlayer insulation film 112 is planarized according to the chemical mechanical polishing (CMP) method.

Next, as shown in FIG. 7G, a resist pattern (not shown) is formed on the second interlayer insulation film 112. With this resist pattern as a mask, the second interlayer insulation film 112 is etched so as to form multiple connection holes. After this, the resist pattern is removed by ashing. The connection holes formed in the second interlayer insulation film 112 are a wiring connection hole 112a, a lower electrode connection hole 112b and an upper electrode connection hole 112c.

Next, as shown in FIG. 7H, a resist pattern (not shown) is formed on the second interlayer insulation film 112. With this resist pattern as a mask, the second interlayer insulation film 112 is etched. After this, the resist pattern is removed by ashing. Consequently, a second wiring groove 112d, a lower electrode wiring groove 112e and an upper electrode wiring groove 112f are formed in the second interlayer insulation film.

Next, as shown in FIG. 7I, a barrier metal film 113 is formed on the surface of all the connection holes and wiring grooves. Subsequently, a Cu layer 114 is deposited on an entire surface and this Cu layer 114 is planarized according to the CMP method. Consequently, a second wiring layer comprised of a second wiring 114d and a wiring plug 114a, a lower electrode wiring layer comprised of a lower electrode wiring 114e and a lower electrode plug 114b, and an upper electrode wiring layer comprised of an upper electrode wiring 114f and an upper electrode plug 114c are formed.

However, according to a conventional manufacturing method, as shown in FIG. 7G, the wiring connection hole 112a, the lower electrode connection hole 112b and the upper electrode connection hole 112c of the MIM-type capacitor 111 need to be each formed in a different depth.

If these connection holes are formed at the same time, the lower electrode film 108a and the upper electrode film 11a of the MIM-type capacitor 111 are over-etched until formation of the deepest wiring connection hole 112a is completed. Thus, there occurs such a problem that the leak characteristic of the capacitor is worsened.

To avoid the above-described problem, it can be considered to form the aforementioned three kinds of connection holes separately. However, in this case, the number of manufacturing steps is increased greatly.

Therefore, a semiconductor device and a method of manufacturing the same which are capable of protecting electrode films in the MIM-type capacitor from damage and allow multiple connection holes to be formed through fewer manufacturing steps have been demanded.

### BRIEF SUMMARY OF THE INVENTION

According to an aspect of the invention, there is provided a semiconductor device comprising: a semiconductor substrate; a first interlayer insulation film formed on the semiconductor substrate; a first wiring layer formed on the first interlayer insulation film, the first wiring layer being exposed on the surface of the first interlayer insulation film; an MIM-type capacitor formed on the first interlayer insulation film, the MIM-type capacitor including: a lower electrode film formed on the first interlayer insulation film; a dielectric film formed on the lower electrode film; an upper electrode film formed on the dielectric film; a second interlayer insulation film formed on the first interlayer insulation film and the MIM-type capacitor; a second wiring layer, a lower electrode wiring and an upper electrode wiring formed on the second interlayer insulation film, the upper electrode wiring being directly in contact with the upper electrode film; a wiring plug which connects the first wiring layer with the second wiring layer; and a lower electrode plug which connects the lower electrode film with the lower electrode wiring.

According to another aspect of the invention, there is provided a semiconductor device comprising: a semiconductor substrate; a first interlayer insulation film formed on the semiconductor substrate; a first wiring layer formed in the interlayer insulation film, the first wiring layer being exposed on the surface of the first interlayer insulation film; a second interlayer insulation film formed on the first interlayer insulation film; a first plug formed on the second interlayer insulation film, the first plug reaching the top face of the first wiring layer; an MIM-type capacitor formed on the side and bottom of the first plug, the MIM-type capacitor including: a lower electrode film connected to the first wiring layer; a dielectric film formed on the lower electrode film; and an upper electrode film formed on the dielectric film; and an upper electrode wiring layer formed on the second interlayer insulation film, the upper electrode wiring layer being connected to the first plug.

According to another aspect of the invention, there is provided a method of manufacturing a semiconductor device, comprising: forming a first interlayer insulation film on a semiconductor substrate; forming a first wiring groove on the first interlayer insulation film; burying a metal film in the first wiring groove so as to form a first wiring layer; forming a lower electrode film on the first interlayer insulation film; forming a capacitor insulation film comprising a dielectric film on the lower electrode film; forming an upper electrode film comprising a second conductive film on the capacitor insulation film; forming a second interlayer insulation film on the first interlayer insulation film and the MIM-type capacitor having the lower electrode film, the capacitor insulation film and the upper electrode film; forming a wiring connection hole reaching the first wiring layer and a lower electrode connection hole reaching the lower electrode film in the second interlayer insulation film; forming a second wiring groove, a lower electrode wiring groove and an upper electrode wiring groove in the second interlayer insulation film, the upper electrode wiring groove reaching the upper electrode film, the second wiring groove communicating with the wiring connection hole, the lower electrode wiring groove communicating with the lower electrode connection hole; and burying a metal film in the wiring connection hole, the lower electrode connection hole, the second wiring groove, the lower electrode wiring groove and the upper electrode wiring groove so as to form the second wiring layer, the lower electrode wiring layer and the upper electrode wiring layer.

According to another aspect of the invention, there is provided a method of manufacturing a semiconductor device, comprising: forming a first interlayer insulation film on a semiconductor substrate; forming multiple first wiring grooves in the first interlayer insulation film; forming multiple first wiring layers by filling each of the first wiring grooves with a metal film; forming a barrier metal film on the first interlayer insulation film and the first wiring layer; forming a second interlayer insulation film on the barrier metal film; forming a wiring connection hole and an electrode connection hole in the second interlayer insulation film, the electrode connection hole reaching the first wiring layer through the barrier metal film; forming a second wiring groove and an electrode wiring groove in the second interlayer insulation film, the second wiring groove communicating with the wiring connection hole, the electrode wiring groove communicating with the electrode connection hole; forming a lower electrode film on the surface of the electrode connection film and the bottom face of the electrode wiring groove; forming a capacitor insulation film comprising a dielectric film on the lower electrode film; forming an upper electrode film comprising the second barrier metal film on the capacitor insulation film, the lower electrode film, the capacitor insulation film and the upper electrode film composing an MIM-type capacitor; and filling the wiring connection hole, the second wiring groove, the electrode connection hole and the electrode wiring groove with a metal film.

### BRIEF DESCRIPTION OF THE SEVERAL VIEWS OF THE DRAWING

FIGS. 1A to 1F are sectional views showing a manufacturing process of a semiconductor device according to a first embodiment of the present invention;

FIGS. 2A to 2E are sectional views showing a manufacturing process of a semiconductor device according to a second embodiment of the present invention;

FIGS. 3A to 3D are sectional views showing a manufacturing process of a semiconductor device according to a third embodiment of the present invention;

FIGS. 4A to 4E are sectional views showing a manufacturing process of a semiconductor device according to a fourth embodiment of the present invention;

FIG. 5A is a sectional view of the semiconductor device according to the fourth embodiment of the present invention;

FIGS. 5B and 5C are sectional views of a top face taken along the line 5B-5B of FIG. 5A;

FIGS. 6A to 6F are sectional views showing a manufacturing process of a semiconductor device according to a fifth embodiment of the present invention; and

FIGS. 7A to 7I are sectional views showing a manufacturing process of a conventional MIM-type capacitor.

### DETAILED DESCRIPTION OF THE INVENTION

[First Embodiment]

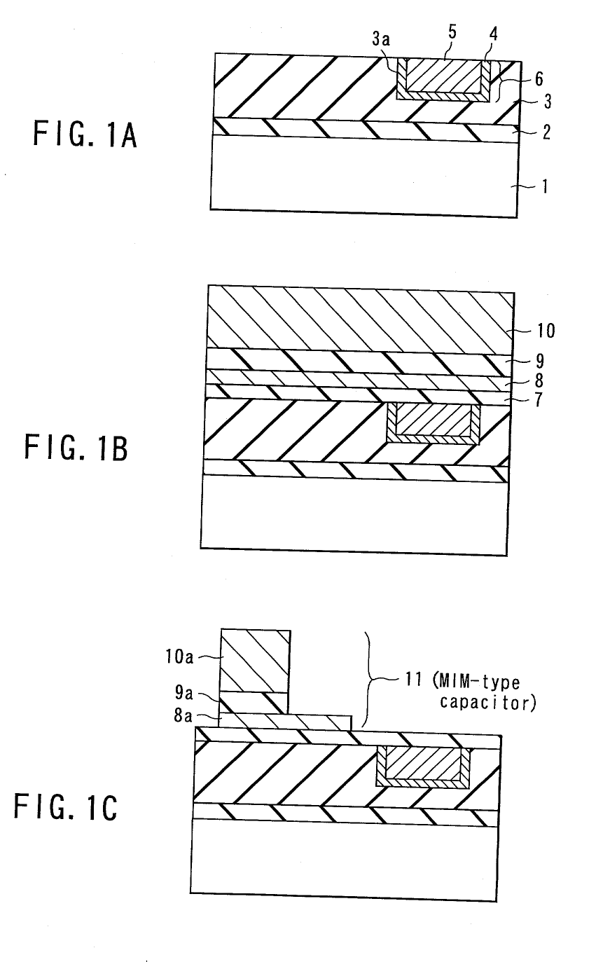

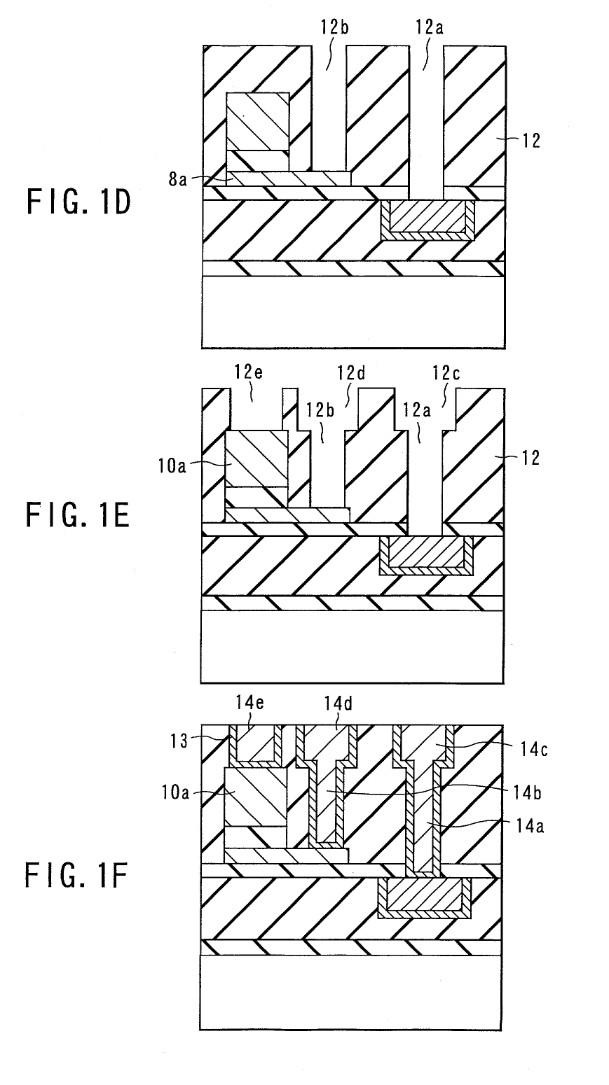

A manufacturing process of a semiconductor device according to a first embodiment of the present invention will be described with reference to FIGS. 1A to 1F.

As shown in FIG. 1A, an insulation film 2, which is an insulation separating film, is formed on a semiconductor substrate 1. Further, a first interlayer insulation film 3 is formed on the insulation film 2. The first interlayer insulation film 3 is made of for example, polymethylsiloxane having a low relative dielectric constant so as to allow the device high-speed operation and reduce its capacitance between wires. Subsequently, a first wiring layer 6 comprised of a first Cu wiring 5 and a barrier metal film 4 is formed. That is, first, a wiring groove 3a is formed in the first interlayer insulation film 3. After that, by depositing a TaN film by about 20 nm on the surface of the wiring groove 3a according to the sputtering method so as to form a barrier metal film 4 in order to prevent diffusion and oxidation of Cu. Further, a Cu film of about 100 nm is deposited on the barrier metal film 4 according to the sputtering method. After that, a Cu film of about 800 nm is deposited on an entire surface of the first interlayer insulation film 3 containing the wiring groove by means of the electrolytic plating method. Further, unnecessary Cu and TaN are removed by polishing according to the CMP method. As a result, the Cu layer 5 is formed so that the first interlayer insulating film 3 is exposed.

Next, as shown in FIG. 1B, a SiN film 7 is deposited on the first interlayer insulation film 3 according to the chemical vapor deposition (CVD) method. This SiN film 7 is a barrier film for preventing diffusion and oxidation of Cu. Subsequently, a first TiN film 8 is deposited by about 40 nm on the barrier film 7 according to the sputtering method. A SiN film 9 is deposited by about 50 nm on the first TiN film 8 according to the CVD method. A second TiN film 10 is deposited by about 300 nm on the SiN film 9 according to the sputtering method.

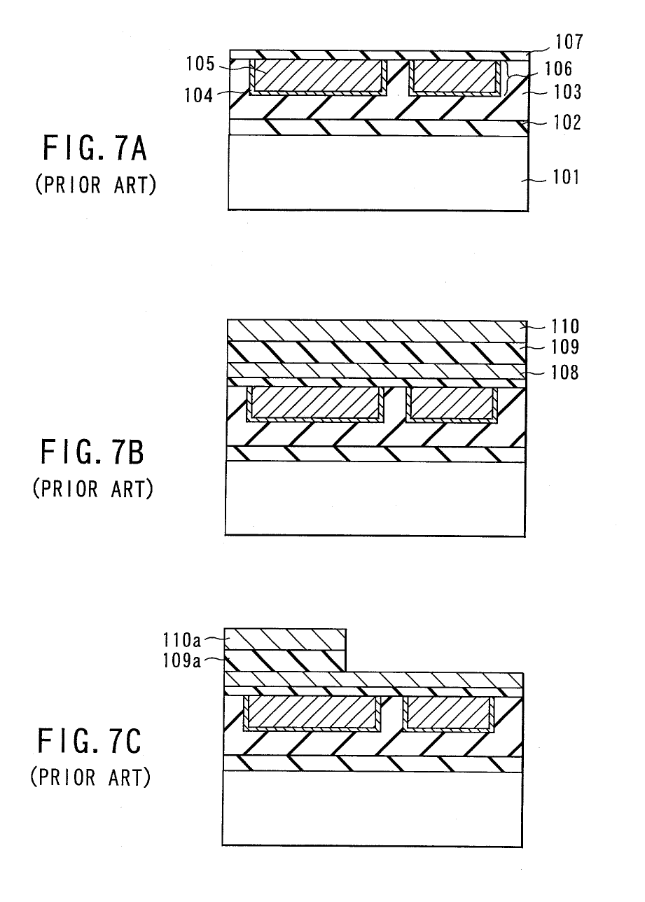

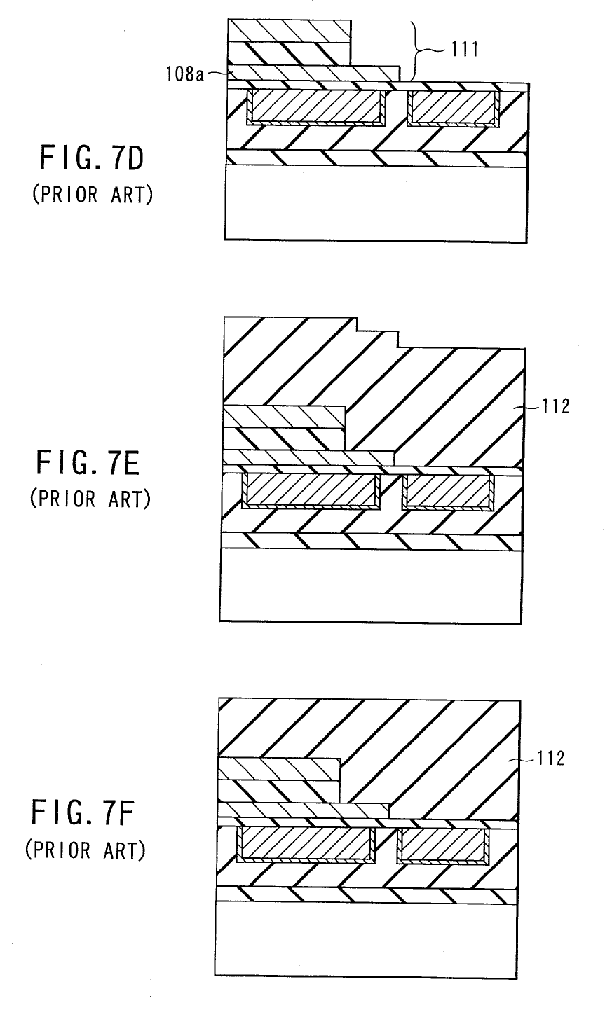

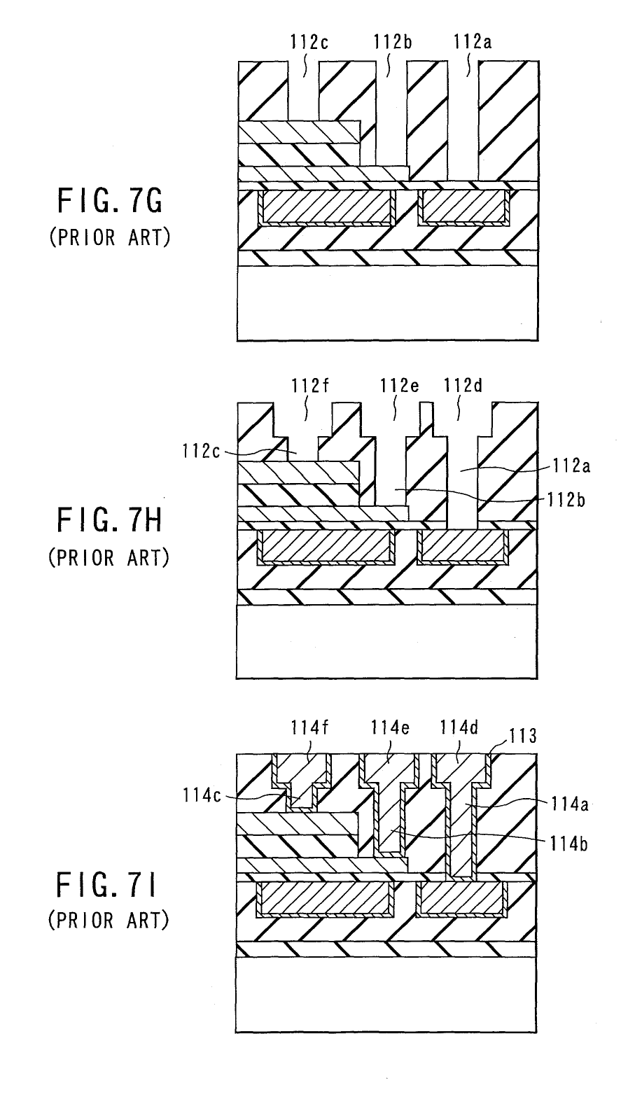

Next, as shown in FIG. 1C, the first TiN film 8, the SiN film 9 and the second TiN film 10 are processed using lithography and RIE technology shown in FIGS. 7C, 7D. Consequently, a lower electrode film 8a, a capacitor insulation film 9a and an upper electrode film 10a of an MIM-type capacitor are formed. By the above described manufacturing process, an MIM-type capacitor 11 is formed.

Next, as shown in FIG. 1D, a second interlayer insulation film 12 is deposited by about 700 nm on the first interlayer insulation film 3. The second interlayer insulation film 12 is planarized according to the CMP method. Further, a wiring connection hole 12a which leads to the first wiring layer 6 and a lower electrode connection hole 12b which leads to the lower electrode film 8a are formed in the second interlayer insulation film 12 by lithography and RIE technology at the same time. The insulation material for the second interlayer insulation film 12 is, for example, polymethylsiloxane like the first interlayer insulation film. Because materials used for the lower electrode film 8a and the second interlayer insulation film 12 are TiN and polymethylsiloxane respectively, the etching rate of both differ. Further, a difference in the depth between the first wiring connection hole 12a and the lower electrode connection hole 12b is equal to the thickness of the lower electrode film 8a, that is, about 40 nm. Thus, the depths of both the connection holes are almost the same. Therefore, if the two connection holes are formed at the same time, the lower electrode film 8a is never over-etched largely.

Next, as shown in FIG. 1E, a second wiring groove 12c, a second wiring groove 12c, a lower electrode wiring groove 12d and an upper electrode wiring groove 12e are formed in the second interlayer insulation film 12 by lithography and RIE technology at the same time. The depth of each groove is about 300 nm. Because the upper electrode film 10a is situated at a depth about 300 nm from a top face of the second interlayer insulation film 12, the upper electrode wiring groove 12e reaches the upper electrode 10a. The wiring grooves 12c, 12d communicate with the connection holes 12a, 12b.

Next, as shown in FIG. 1F, a TaN film is deposited by about 20 nm on the surface of the second interlayer insulation film including the connection holes and wiring grooves according to the sputtering method so as to form a barrier metal film 13. Further, a Cu film about 100 nm thick is deposited on the barrier metal film 13 according to the sputtering method. After this, Cu layer about 800 nm thick is deposited on an entire surface of the second interlayer insulation film 12 containing all the connection holes and wiring grooves according to the electrolytic plating method. Further, unnecessary Cu layer and TaN are removed by polishing until the second interlayer insulation film 12 is exposed, according to the CMP method, so that the Cu layer is planarized. Consequently, a second wiring layer, a lower electrode wiring layer and an upper electrode wiring layer are formed. The second wiring layer is composed of a second wiring 14c and a wiring plug 14a. The lower electrode wiring layer is composed of a lower electrode wiring 14d and a lower electrode plug 14b. The second interlayer insulation film 12 is composed of an upper electrode wiring 14e. The upper electrode wiring layer is connected directly to the upper electrode 10a without through any plug. That is, the thickness of the second interlayer insulation film 12 on the upper electrode 10a is almost equal to the thickness of each film of the second wiring layer, the lower electrode wiring layer and the upper electrode wiring layer. Further, the depth of the lower electrode plug 14b is almost equal to the total of the thickness of the capacitor insulation film 9a plus the thickness of the upper electrode film 10a.

According to the first embodiment, the thickness of the upper electrode film 10a is adjusted so as to be almost equal to the depth of each of the second interlayer insulation film 12 on the upper electrode film 10a, the second wiring groove 12c, the lower electrode wiring groove 12d and the upper electrode wiring groove 12e. Thus, formation of the upper electrode connection hole is unnecessary, so that over-etching of the upper electrode film 10a can be avoided. Thus, the characteristic of an excellent MIM-type capacitor can be maintained. Further, because multiple connection holes 12a, 12b and wiring grooves 12c to 12e can be formed at the same time, increase of manufacturing processes can be avoided.

[Second Embodiment]

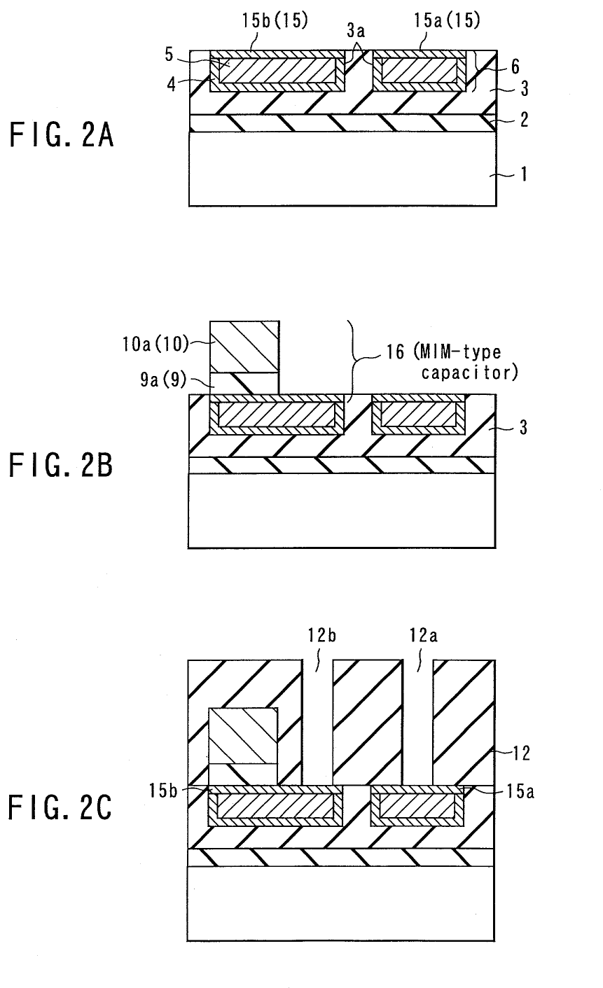

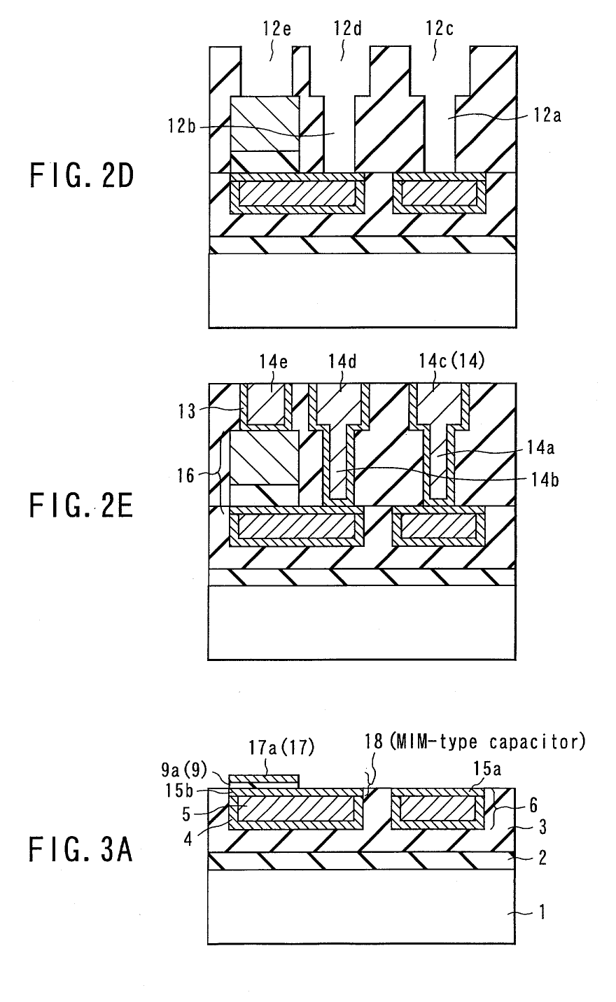

Next, a manufacturing process of a semiconductor device according to a second embodiment of the present invention will be described with reference to FIGS. 2A to 2E.

As shown in FIG. 2A, an insulation film 2, which is an insulation separating layer, is formed on a semiconductor substrate 1 like the first embodiment. A first interlayer insulation film 3 is formed on this insulation film 2. Subsequently, a wiring groove 3a is formed in the first interlayer insulation film 3 and after that, a TaN film 4 is deposited as a barrier metal film on the surface of the wiring groove 3a. Further, a Cu layer 5 is deposited on the TaN film 4 so as to bury the wiring groove 3a. Next, unnecessary Cu layer 5 and TaN film 4 are removed by polishing according to the CMP method so as to planarize the surface. After that, a recess portion of about 50 nm is formed only in the Cu layer 5. Then, a TaN film 15, which becomes barrier metal films 15a, 15b, is deposited according to the sputtering method. In order to form the TaN film 15 on only the top face of the Cu layer 5, an excessive portion of the TaN film 15 deposited on the first interlayer insulation film 3 is removed by polishing according to the CMP method. Consequently, the barrier metal film 15b is formed on a top face of a first Cu wiring layer 6 in which a capacitor insulation film is to be formed, in a subsequent manufacturing process. Then, the barrier metal film 15a is formed on the top face of the first Cu wiring layer 6 in which no capacitor insulation film is formed.

Next, a SiN film 9 is formed by about 50 nm on the first interlayer insulation film 3 as shown in FIG. 2B. A TaN film 10 is deposited on the SiN film 9. Further, the SiN film 9 and the TaN film 10 are processed using lithography and RIE technology. Consequently, a capacitor insulation film 9a and an upper electrode film 10a of an MIM-type capacitor are formed.

In the above-described manufacturing process, an MIM-type capacitor 16, in which the barrier metal film 15b acts as a lower electrode film, is formed. Therefore, the barrier metal film 15b which prevents diffusion and oxidation of a first Cu wiring 5 takes a role as the lower electrode film of the MIM-type capacitor also.

Next, as shown in FIG. 2C, a second interlayer insulation film 12 is deposited by about 700 nm on the first interlayer insulation film 3 and then, the second interlayer insulation film 12 is planarized according to the CMP method. At this time, the thickness of the second interlayer insulation film 12 on the upper electrode film 10a is adjusted so as to be substantially equal to the depth of the wiring groove to be formed later. Further, a first wiring connection hole 12a and a lower electrode connection hole 12b are formed in the second interlayer insulation film 12 according to lithography and RIE technology. The first wiring connection hole 12a reaches the first wiring layer 6 while the lower electrode connection hole 12b reaches the lower electrode film 15b. Because the depth of the first wiring connection hole 12a is equal to that of the lower electrode connection hole 12b, the lower electrode film 15b is never over-etched.

Next, as shown in FIG. 2D, a second wiring groove 12c, a lower electrode wiring groove 12d and an upper electrode wiring groove 12e are formed in the second interlayer insulation film 12 at the same time using lithography and RIE technology. The depth of each of the wiring holes 12c, 12d and 12e is about 300 nm. The upper electrode film 10a is situated about 300 nm deep from the top face of the second interlayer insulation film 12. Therefore, the upper electrode wiring groove 12e reaches the upper electrode film 10a.

Next, as shown in FIG. 2E, a barrier metal film 13 is deposited on the surface of all the connection holes and wiring grooves. Further, all the connection holes and wiring grooves are buried by a Cu layer 14 so as to planarize the surface. Consequently, a second wiring layer comprised of a second wiring 14c and a wiring plug 14a, a lower electrode wiring layer comprised of a lower electrode wiring 14d and a lower electrode plug 14b, and an upper electrode wiring layer composed of an upper electrode wiring 14e are formed as in the first embodiment.

According to the second embodiment, the upper electrode film 10a of the MIM-type capacitor 16 is connected to the upper electrode wiring 14e without through any connection hole. Therefore, upon formation of the connection holes, over-etching of the lower electrode film 15b and the upper electrode film 10a of the MIM-type capacitor 16 can be avoided. Further, because multiple connection holes and wiring grooves can be formed at the same time, increase of the manufacturing processes can be avoided.

[Third Embodiment]

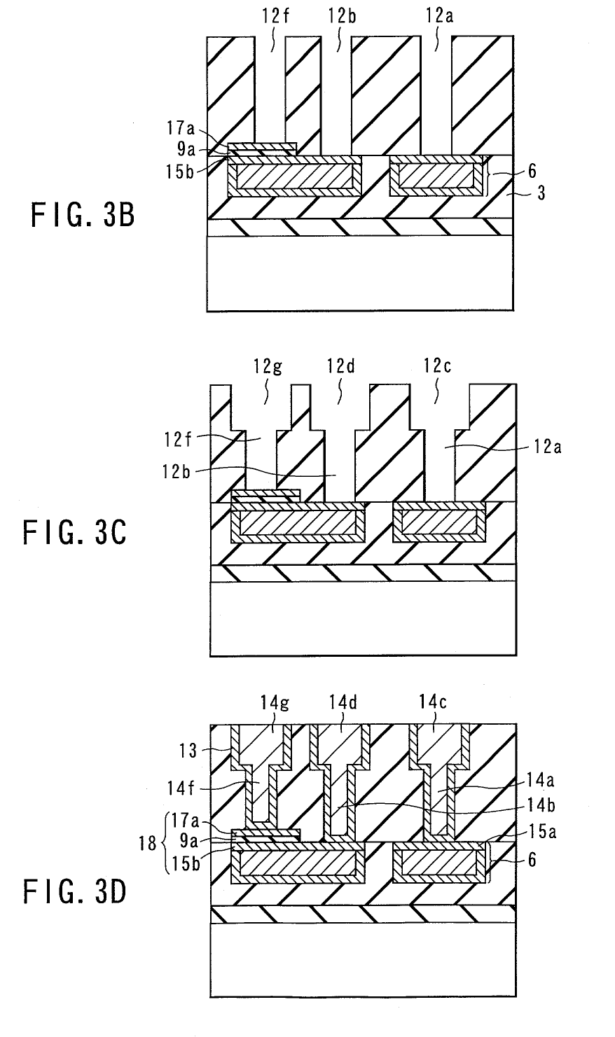

Next, a manufacturing process of a semiconductor device according to a third embodiment of the present invention will be described with reference to FIGS. 3A to 3D.

Because the manufacturing process (FIG. 2A) for forming a first wiring layer 6 in the third embodiment is the same as the second embodiment, description thereof is omitted.

Next, as shown in FIG. 3A, an SiN film 9 is deposited by about 50 nm on the first interlayer insulation film 3. Subsequently, a TaN film 17 is deposited by about 60 nm on the SiN film 9. Further, the SiN film 9 and the TaN film 17 are processed using lithography and RIE technology so as to form a capacitor insulation film 9a and an upper electrode film 17a of an MIM-type capacitor. In the above described manufacturing process, an MIM-type capacitor 18 in which the barrier metal film 15b serves as the lower electrode film is formed.

Next, as shown in FIG. 3B, a second interlayer insulation film 12 is deposited by about 700 nm on the first interlayer insulation film 3. Next, the second interlayer insulation film 12 is planarized according to the CMP method. Further, a first wiring connection hole 12a, a lower electrode connection hole 12b and an upper electrode connection hole 12f are formed in the second interlayer insulation film 12 using lithography and RIE technology at the same time. The first wiring connection hole 12a reaches the first wiring layer 6. The lower electrode connection hole 12b reaches the lower electrode film 15b. The upper electrode connection hole 12f reaches the upper electrode film 17a. The upper electrode connection hole 12f is shallower than the other two connection holes. For is reason, over-etching of the upper electrode film 17a is a possible problem. However, the material used at the bottoms of these three connection holes is all formed of the TaN film. Therefore, because the second interlayer insulation film 12 and the upper electrode film 17a each have a different etching rate, the upper electrode film 17a takes a role as an etching stopper. Further, the thickness of each of the capacitor insulation film 9a and the upper electrode film 17a is small. Therefore, the depth of each of the first wiring connection hole 12a and the lower electrode connection hole 12b is almost equal to that of the upper electrode connection hole 12f. That is, the thickness of each of the second interlayer insulation film 12 on the first wiring layer 6, the lower electrode film 15b and the upper electrode film 17a is almost the same. Therefore, the upper electrode film 17a is never over-etched greatly.

Next, as shown in FIG. 3C, a second wiring groove 12c, a lower electrode wiring groove 12d and an upper electrode wiring groove 12g are formed by about 300 nm in the second interlayer insulation film 12 using lithography and RIE technology.

As shown in FIG. 3D, a barrier metal film 13 is deposited on the surface of all the connection holes and wiring grooves. Further, all the connection holes and wiring grooves are buried with a Cu layer 14 so as to planarize the surface thereof. Consequently, a second wiring layer comprised of a second wiring 14a and a wiring plug 14c, a lower electrode wiring layer comprised of a lower electrode wiring 14d and a lower electrode plug 14b, and an upper electrode wiring layer comprised of an upper electrode wiring 14g and an upper electrode plug 14f are formed like the first embodiment.

According to the third embodiment, the barrier metal film 15a on the top face of the first wiring layer 6, the lower electrode film 15b and the upper electrode film 17a are formed of the same material. Further, the etching grade of these films 15a, 15b and 17a is different from that of the second insulation film 12. The MIM-type capacitor 18 is thinner than the first and second embodiments. Thus, excessive over-etching of the upper electrode film 17a can be avoided. Further, because the multiple connection holes and wiring grooves are formed at the same time, increase of manufacturing processes can be avoided.

[Fourth Embodiment]

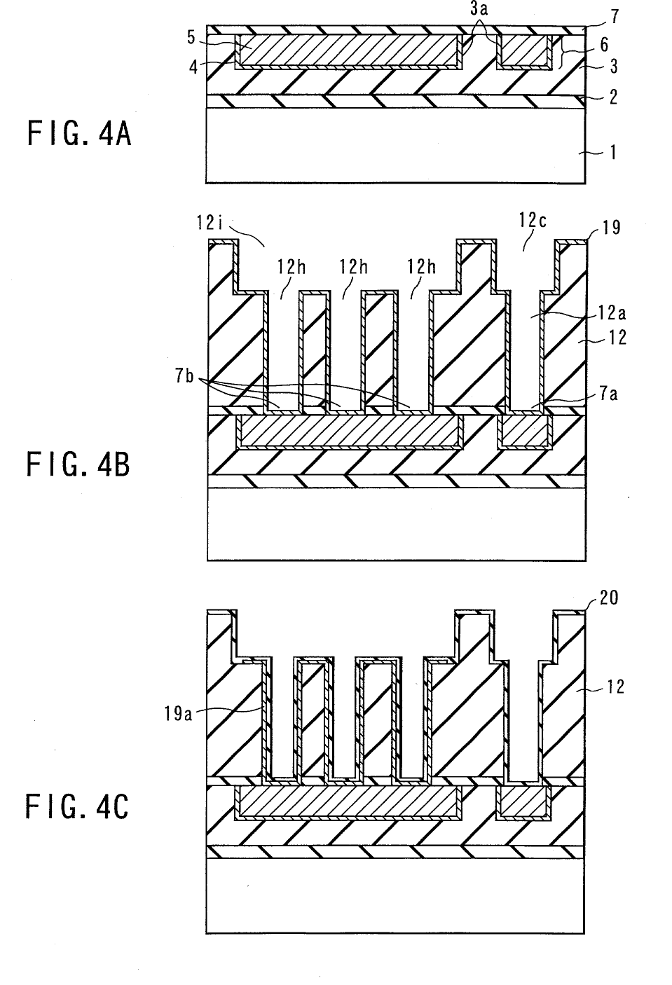

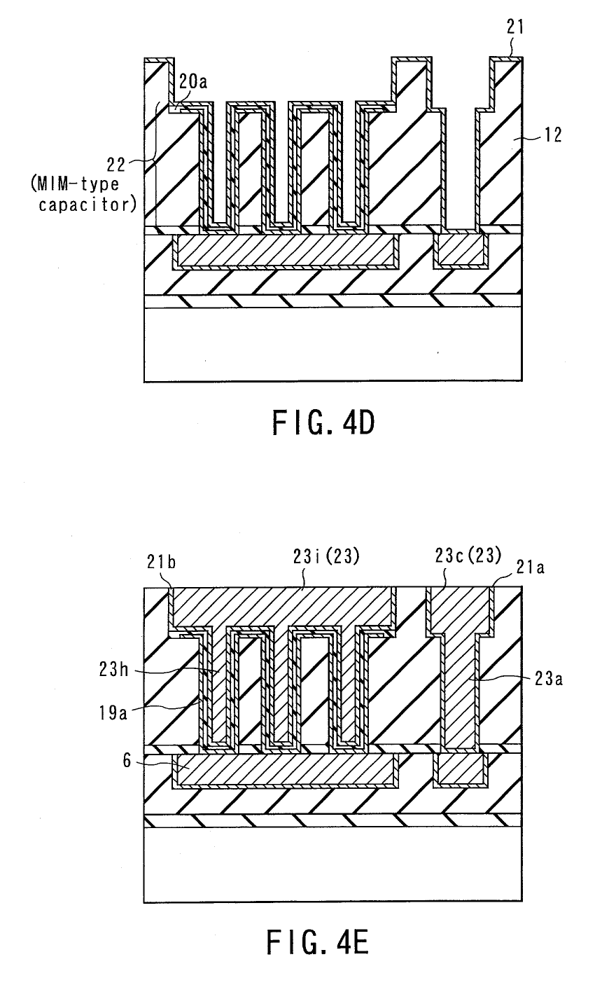

Next, a manufacturing process of a semiconductor device according to a fourth embodiment of the present invention will be described with reference to FIGS. 4A to 4E.

As shown in FIG. 4A, an insulation film 2, which is an insulation separating layer, is formed on a semiconductor substrate 1. A first interlayer insulation film 3 is formed on the insulation film 2. Subsequently, a wiring groove 3a is formed in the first interlayer insulation film 3. After that, a TaN film 4 is deposited as a barrier metal film on the surface of the wiring groove 3a and the wiring groove 3a is buried by depositing a Cu layer 5. Next, unnecessary Cu layer 5 and TaN film 4 are removed by polishing according to the CMP method so as to planarize the surface. Consequently, multiple first wiring layers 6, composed of the TaN film 4 and Cu layer 5, are formed. After that, an SiN film 7 is deposited as a barrier film for preventing diffusion and oxidation of Cu on the first interlayer insulation film 3.

Next, as shown in FIG. 4B, a second interlayer insulation film 12 is deposited by about 700 nm on the first interlayer insulation film 3. A wiring connection hole 12a and multiple electrode insulation holes 12h, which lead to the first wiring layer 6, are formed in the second interlayer insulation film 12 using lithography and RIE technology. Subsequently, a second wiring groove 12c and an electrode wiring groove 12i are formed using lithography and RIE technology. The second wiring groove 12c communicates with the wiring connection hole 12a while the electrode wiring groove 12i communicates with the multiple electrode connection holes 12h. Further, the barrier film 7 on the bottom of the connection holes 12a and 12h is removed with the RIE technology so as to form grooves 7a, 7b. Next, a TaN film 19 is deposited by about 40 nm on the surface of all the wiring grooves and connection holes according to the sputtering method.

Next, as shown in FIG. 4C, the TaN film 19 is processed using lithography and RIE technology and the TaN film 19 except for the electrode wiring groove 12i and the multiple electrode connection holes 12h is removed. Then, the TaN film 19a is formed on the electrode wiring groove 12i and the multiple electrode connection holes 12h. This TaN film 19a forms a lower electrode film of an MIM-type capacitor. Further, an SiN film 20 is deposited by about 50 nm on the surface of the connection hole and wiring groove in the TaN film 19a and the second interlayer insulation film 12 according to the CVD method.

Next, as shown in FIG. 4D, the SiN film 20 is processed using lithography and RIE technology and then, the SiN film 20 except for the electrode wiring groove 12i and the multiple electrode connection holes 12h is removed. An SiN film 20a is formed on the electrode wiring groove 12i and the multiple electrode connection holes 12h. This SiN film 20a forms a capacitor insulation film of the MIM-type capacitor. A TaN film 21 is deposited on the surface of the SiN film 20a and the second interlayer insulation film 12 according to the sputtering method.

Next, as shown in FIG. 4E, a Cu film (not shown) of about 100 nm is deposited on the TaN film 21 according to the sputtering method. After that, a Cu layer 23 of about 800 nm is deposited on the entire surface of the second interlayer insulation film 12 including the wiring groove according to the electrolytic plating method. Further, unnecessary Cu and TaN are removed by polishing according to the CMP method so as to planarize the Cu layer 23. Consequently, a second wiring layer comprised of a second wiring 23c and a wiring plug 23a and an electrode wiring layer comprised of an electrode wiring 23i and an electrode plug 23h are formed. The TaN film 21 forms a barrier metal film 21a so as to prevent diffusion and oxidation of the first and second Cu wiring layers and further forms the barrier metal film for the electrode wiring and an upper electrode film 21b for an MIM-type capacitor 22.

Here, description about formation of the lower electrode plug is omitted, however the lower electrode plug can be formed at the same time as the wiring plug 23a and the electrode plug 23h. That is, when forming the wiring connection hole 12a and the electrode connection hole 12h, the lower electrode connection hole is formed corresponding to the first wiring layer 6 in contact with the lower electrode film 19. Further, the TaN film 21 and the Cu layer 23, which form the barrier metal film, are deposited on the lower electrode connection hole in the manufacturing process shown in FIG. 4E and by removing these by polishing according to the CMP method, the lower electrode plug is formed. In the meantime, the upper electrode plug corresponds to the electrode plug 23h while the upper electrode wiring corresponds to the electrode wiring 23i.

According to the fourth embodiment, the depths of all the connection holes are the same. For this reason, over-etching on lower layers due to a difference in the depth of the connection holes never occurs. Further, the barrier metal film 21a of the wiring layer and the upper electrode film 21b of the MIM-type capacitor can be formed at the same time. Consequently, increase of manufacturing processes can be avoided.

The MIM-type capacitor 22 of the fourth embodiment has a solid structure. Thus, it is possible to produce a capacitor having a larger capacitance than a parallel flat plate capacitor. If it is intended to increase the electrode area of the MIM-type capacitor, the quantity of the electrode connection holes 12h only has to be increased (according to this embodiment, three electrode connection holes are provided).

Further, the electrode area of the MIM-type capacitor may be increased by the shape of the electrode connection hole 12h.

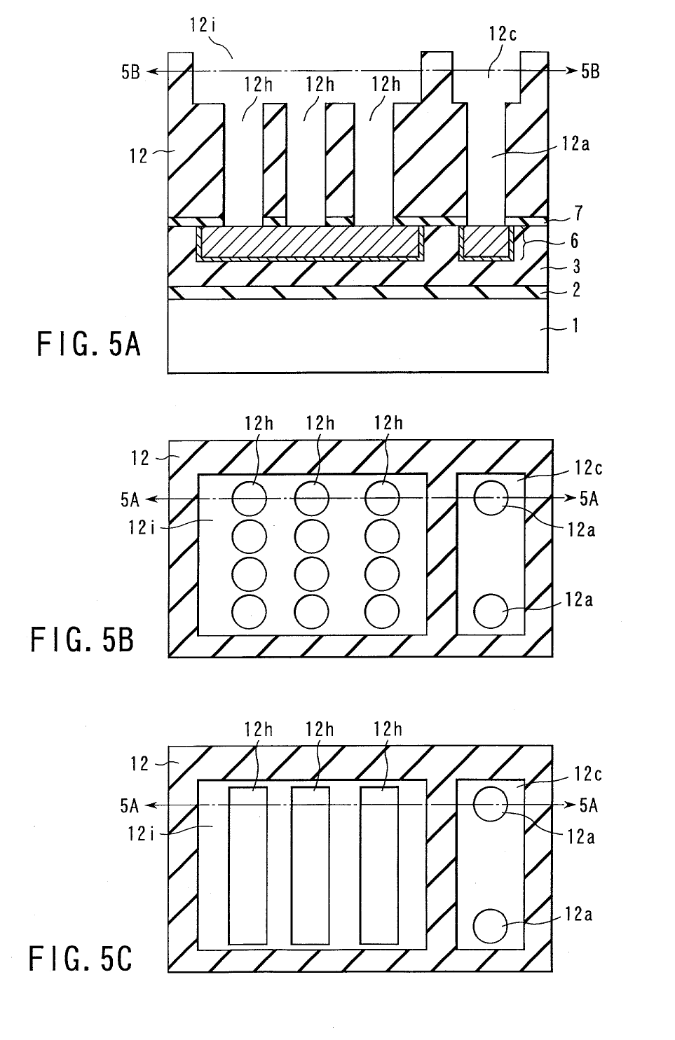

For example, as shown in FIG. 5B, cylindrical electrode connection holes 12h are disposed continuously. FIG. 5B shows a sectional view of a top face taken along the line 5B-5B of FIG. 5A. FIG. 5A is a side sectional view of the semiconductor device according to the fourth embodiment, showing the structure after all the wiring grooves and connection holes are formed in the second interlayer insulation film 12 according to the dual damascene method.

As shown in FIG. 5C, the electrode connection hole 12h is formed in the shape of a groove whose horizontal section is rectangular. Such a structure is capable of enlarging the electrode area of the MIM-type capacitor. FIG. 5C shows a section of the top face taken along the line 5B-5B of FIG. 5A.

According to the fourth embodiment, the second interlayer insulation film 12 is deposited on the flat barrier film 7. Thus, the second interlayer insulation film does not have to be removed by polishing according to the CMP method. An insulation material having a low dielectric constant such as polymethylsiloxane to be used as the interlayer insulation material is likely to be damaged by polishing according to the CMP method. Because the fourth embodiment does not need a step for polishing the interlayer insulation film, it can maintain an excellent device characteristic.

[Fifth Embodiment]

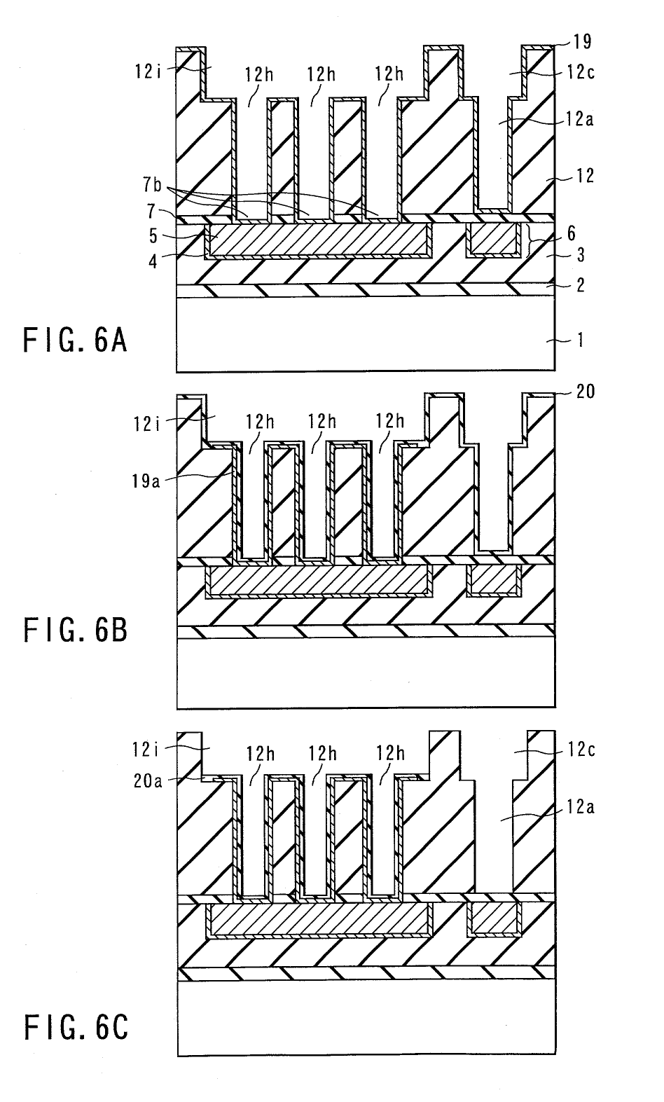

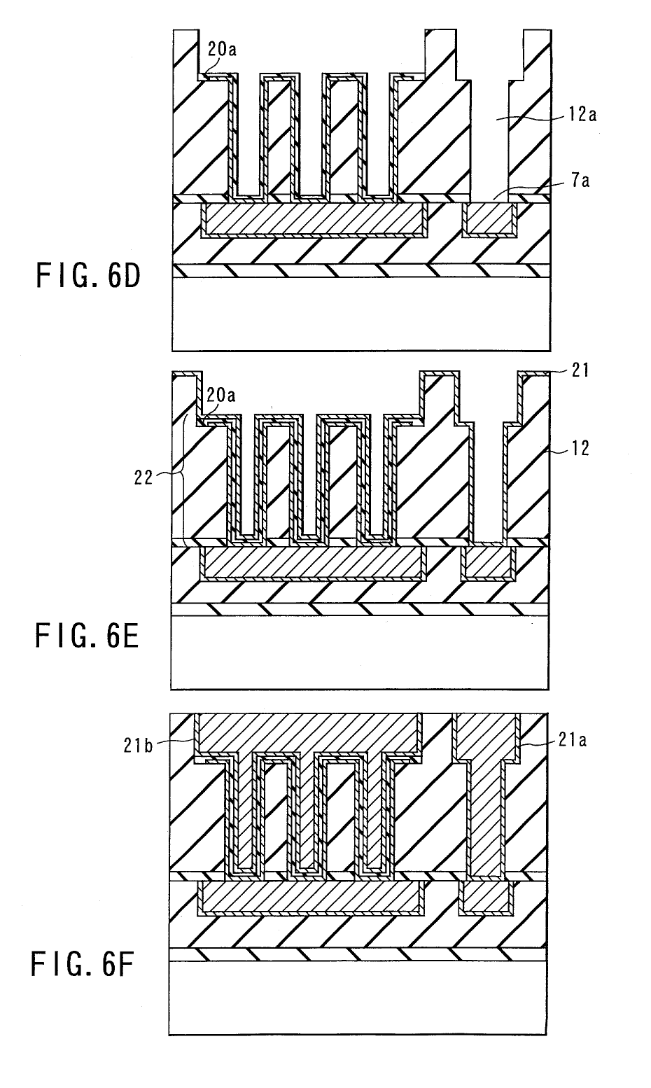

A manufacturing process of a semiconductor device according to a fifth embodiment of the present invention will be described with reference to FIGS. 6A to 6F.

Because according to the fifth embodiment, the manufacturing process (FIG. 4A) up to the formation of a barrier film 7 is the same as the fourth embodiment, description thereof is omitted.

As shown in FIG. 6A, a second interlayer insulation film 12 is deposited by about 700 nm on the barrier film 7. A wiring connection hole 12a and multiple electrode connection holes 12h, which lead to the first wiring layer 6, are formed in the second interlayer insulation film 12 using lithography and RIE technology. Subsequently, a second wiring groove 12c and an electrode wiring groove 12i are formed using lithography and RIE technology. The second wiring groove 12c communicates with the wiring connection hole 12a, while the electrode wiring groove 12i communicates with the multiple electrode connection holes 12h. Further, the barrier film 7 on the bottom of each electrode connection hole 12h is removed by the RIE technology.

In the fourth embodiment, the groove 7b in the barrier film 7 and the groove 7a in the wiring connection hole 12a shown in FIG. 4B are formed at the same time. However, according to the fifth embodiment, the groove 7a in the wiring connection hole 12a is formed in a subsequent step. This protects the first wiring layer 6 from damage due to lithography, RIE, resist separation and the like repeated in the process for formation of the MIM-type capacitor.

Next, a TaN film 19 is deposited by about 40 nm on the surface of all the wiring grooves and connection holes according to the sputtering method.

As shown in FIG. 6B, the TaN film 19 is processed using lithography and RIE technology and the TaN film 19 except for the electrode wiring groove 12i and the multiple electrode connection holes 12h is removed. Then, the TaN film 19 is formed on the electrode wiring groove 12i and the multiple electrode connection holes 12h. This TaN film 19a forms a lower electrode film of an MIM-type capacitor. An SiN film 20 is deposited by about 50 nm on the surface of the connection hole and the wiring groove in the TaN film 19a and the second interlayer insulation film 12 according to the plasma CVD method.

Next, as shown in FIG. 6C, the SiN film 20 is processed using lithography and RIE technology and the SiN film 20 except for the electrode wiring groove 12i and the electrode connection holes 12h is removed. Then, an SiN film 20a is formed on the electrode wiring groove 12i and the multiple electrode connection holes 12h. This SiN film 20a forms a capacitor insulation film of the MIM-type capacitor.

As shown in FIG. 6D, the barrier film 7 is removed from the bottom of the first wiring connection hole 12a according to the RIE technology so as to form the groove 7a.

Next, as shown in FIG. 6E, a TaN film 21 is deposited by about 60 nm on the surface of the SiN film 20a and the second interlayer insulation film 12. Subsequently, a Cu film of about 100 nm is deposited on the TaN film 21 according to the sputtering method. Consequently, a Cu film 23 of about 800 nm is deposited on that structure according to the electrolytic plating method. After that, the unnecessary Cu layer and TaN film are removed by polishing so as to planarize the Cu layer 23, so that the second interlayer insulation film 12 is exposed.

According to the fifth embodiment, the MIM-type capacitor 22, in which the TaN film 21b acts as the upper electrode film, can be formed as in the fourth embodiment. According to the fifth embodiment, the wiring layer except for the region in which the MIM-type capacitor 22 is formed is exposed just before the upper electrode film 21b of the MIM-type capacitor and the barrier metal film 21a of the first wiring layer are deposited. Thus, oxidation and corrosion of the surface of the Cu layer 5 can be avoided.

According to the above-described respective embodiments, the TiN film or the TaN film is used as material for the upper and lower electrode films of the MIM-type capacitor. However, the present invention is not restricted to this example; it is permissible to use for example, WN, W—Si—N or Ti—Si—N as metallic conductive material having the function for preventing diffusion and oxidation of Cu and a high work function.

In the respective embodiments, the SiN film is employed as the capacitor insulation film. However, the present invention is not restricted to this example, and it is permissible to use a dielectric film such as SiON film or Ta₂O₅ film.

Further, the interlayer insulation film is not restricted to polymethylsiloxane. However, an insulation film having a low dielectric constant is desired to operate the device at high speeds. Further, the etching rate needs to be different from that of the capacitor insulation film such as TaN. As a material which satisfies these conditions, it is permissible to use for example, polyarylane ether or HSQ (product name: FOx).

Although Cu is employed as the wiring material, it is permissible to use another metal such as Al, Au, Ag, or W instead of the Cu.

In the above-described respective embodiments, the MIM-type capacitor is formed between the first and second interlayer insulation films. However, the present invention is not restricted to this example, and it is permissible to apply the respective embodiments to a case where the MIM-type capacitor is formed between the second and third interlayer insulation films or at other interlayer positions.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a first interlayer insulation film formed on said semiconductor substrate;
a first wiring layer formed on said first interlayer insulation film, said first wiring layer being exposed on the surface of said first interlayer insulation film;
an MIM-type capacitor formed on said first interlayer insulation film, said MIM-type capacitor including:
a lower electrode film formed on said first interlayer insulation film;
a dielectric film formed on said lower electrode film;
an upper electrode film formed on said dielectric film;
a second interlayer insulation film formed on said first interlayer insulation film and said MIM-type capacitor;
a second wiring layer, a lower electrode wiring and an upper electrode wiring formed on said second interlayer insulation film, said upper electrode wiring being directly in contact with said upper electrode film;
a wiring plug which connects said first wiring layer with said second wiring layer; and
a lower electrode plug which connects said lower electrode film with said lower electrode wiring.

2. The device according to claim 1, wherein the thickness of the second interlayer insulation film on said upper electrode film is substantially equal to the thickness of each of said second wiring layer, said lower electrode wiring and said upper electrode wiring.

3. The device according to claim 1, wherein the depth of said lower electrode plug is substantially equal to the total of the thickness of said capacitor insulation film and said upper electrode film.

4. The device according to claim 3, wherein said lower electrode film and said upper electrode film are formed of at least one material selected from the group consisting of TaN, TiN, WN, W—Si—N, Ti—Si—N, and Ta—Si—N.

5. A semiconductor device comprising:
a semiconductor substrate;
a first interlayer insulation film formed on said semiconductor substrate;
a first wiring layer formed in said first interlayer insulation film, said first wiring layer having a groove formed in said interlayer insulation film and a metal film buried in the groove and being exposed on the surface of said first interlayer insulation film;
an MIM-type capacitor formed on the top face of a first portion of said first wiring layer, said MIM-type capacitor including:
said first wiring layer;
a dielectric film formed on the top face of the first portion of said first wiring layer;
an upper electrode film comprising a conductive film formed on said dielectric film;
a second interlayer insulation film formed on said MIM-type capacitor and said first interlayer insulation film;
a lower electrode wiring formed in said second interlayer insulation film;
a lower electrode plug formed in said second interlayer insulation film, said lower electrode plug connecting a second portion of said first wiring layer with said lower electrode wiring; and
an upper electrode wiring formed in said second interlayer insulation film, said upper electrode wiring being connected directly to said upper electrode film.

6. The device according to claim 5, further comprising:
a second wiring formed in said first interlayer insulation film;
a third wiring layer formed in said second interlayer insulation film; and
a wiring plug formed in said second interlayer insulation film, said wiring plug connecting said second wiring layer with said third wiring layer.

7. The device according to claim 5, wherein said first wiring layer comprises a metal wiring and a barrier metal film formed on the top face of said metal wiring.

8. The device according to claim 5, wherein the thickness of the second interlayer insulation film on said upper electrode film is substantially equal to the thickness of each of the lower electrode wiring and the upper electrode wiring.

9. A semiconductor device comprising:
a semiconductor substrate;
a first interlayer insulation film formed on said semiconductor substrate;
first and second wiring layers formed in said first interlayer insulation film, said first and second wiring layers being exposed on the surface of said first interlayer insulation film;
an MIM-type capacitor formed on the top face of a first portion of said first wiring layer, said MIM-type capacitor including:
said first wiring layer;
a dielectric film formed on the top face of the first portion of said first wiring layer; and
an upper electrode film comprising a conductive film formed on said dielectric film;
a second interlayer insulation film formed on said MIM-type capacitor and said first interlayer insulation film, the thickness of each of said second interlayer insulation film on said second wiring layer, said second interlayer insulation film on a second portion of said first wiring layer and said second interlayer insulation film on said upper electrode film being set substantially equal;
a third wiring layer, a lower electrode wiring layer and an upper electrode wiring layer formed in said second interlayer insulation film;
a first plug formed in said second interlayer insulation film, said first plug connecting said second wiring layer with the third wiring layer;
a second plug formed in said second interlayer insulation film, said second plug connecting said lower electrode wiring layer with the second portion of the first wiring layer; and
a third plug formed in said second interlayer insulation film, said third plug connecting said upper electrode wiring layer with said upper electrode film.

10. The device according to claim 3, wherein said lower electrode film and said upper electrode film are formed of at least one material selected from the group consisting of TaN, TiN, WN, W—Si—N, Ti—Si—N, and Ta—Si—N.

11. A semiconductor device comprising:
a semiconductor substrate;
a first interlayer insulation film formed on said semiconductor substrate;
a first wiring layer formed in said interlayer insulation film, said first wiring layer being exposed on the surface of said first interlayer insulation film;
a second interlayer insulation film formed on said first interlayer insulation film;
a first plug formed on said second interlayer insulation film, said first plug reaching the top face of said first wiring layer;
an MIM-type capacitor formed on the side and bottom of said first plug, said MIM-type capacitor including:
a lower electrode film connected to said first wiring layer;
a dielectric film formed on said lower electrode film; and
an upper electrode film formed on said dielectric film; and
an upper electrode wiring layer formed on said second interlayer insulation film, said upper electrode wiring layer being connected to said first plug.

12. The device according to claim 11, further comprising:
a second wiring layer formed on said first interlayer insulation film;
a second plug formed on said second interlayer insulation film, said second plug reaching the top face of said second wiring layer; and
a third wiring layer formed on said second interlayer insulation film, said third wiring layer being connected to said second plug.

13. The device according to claim 12, wherein the depth of said first plug is substantially the same as the depth of said second plug.

14. The device according to claim 11, wherein said lower electrode film and said upper electrode film are formed of at least one material selected from the group consisting of TaN, TiN, WN, W—Si—N, Ti—Si—N, and Ta—Si—N.

15. The device according to claim 12, wherein said second plug has a barrier metal film on a side face thereof.

16. The device according to claim 15, wherein said barrier metal film is formed of the same material as said upper electrode film.

17. The device according to claim 11, wherein said first plug is provided in each of multiple cylindrical openings.

18. The device according to claim 11, wherein said first plug is provided in each of rectangular openings.

19. A method of manufacturing a semiconductor device, comprising:
forming a first interlayer insulation film on a semiconductor substrate;
forming a first wiring groove on said first interlayer insulation film;
burying a metal film in said first wiring groove so as to form a first wiring layer;
forming a lower electrode film on said first interlayer insulation film;
forming a capacitor insulation film comprising a dielectric film on said lower electrode film;
forming an upper electrode film comprising a second conductive film on said capacitor insulation film;
forming a second interlayer insulation film on said first interlayer insulation film and the MIM-type capacitor having said lower electrode film, the capacitor insulation film and the upper electrode film;
forming a wiring connection hole reaching said first wiring layer and a lower electrode connection hole reaching said lower electrode film in said second interlayer insulation film;
forming a second wiring groove, a lower electrode wiring groove and an upper electrode wiring groove in said second interlayer insulation film, said upper electrode wiring groove reaching said upper electrode film, said second wiring groove communicating with the wiring connection hole, the lower electrode wiring groove communicating with the lower electrode connection hole; and
burying a metal film in said wiring connection hole, the lower electrode connection hole, the second wiring groove, the lower electrode wiring groove and the upper electrode wiring groove so as to form the second wiring layer, the lower electrode wiring layer and the upper electrode wiring layer.

20. The method according to claim 19, wherein said lower electrode film and said upper electrode film are formed of at least one material selected from the group consisting of TaN, TiN, WN, W—Si—N, Ti—Si—N, and Ta—Si—N.

21. A method of manufacturing a semiconductor device, comprising:
forming a first interlayer insulation film on a semiconductor substrate;
forming a first wiring groove in said first interlayer insulation film;
forming a metal film in said first wiring groove;
forming a barrier metal film on the top face of said metal film so as to form a first wiring layer comprising said metal film and said barrier metal film;
forming a dielectric film on the top face of a first portion of said first wiring layer;
forming a conductive film on said dielectric film so as to form an MIM-type capacitor, said MIM-type capacitor having said first wiring layer as a lower electrode film, said dielectric film as a capacitor insulation film and said conductive film as an upper electrode film;
forming a second interlayer insulation film on said first interlayer insulation film and the MIM-type capacitor;
forming a wiring connection hole and a lower electrode connection hole in said second interlayer insulation film;
forming a second wiring groove, a lower electrode wiring groove and an upper electrode wiring groove in said second interlayer insulation film, said upper electrode wiring groove reaching said upper electrode film, said second wiring groove communicating with said wiring connection hole, said lower electrode wiring groove communicating with the lower electrode connection hole; and
burying a metal film in said wiring connection hole, the lower electrode connection hole, the second wiring groove, the lower electrode wiring groove and the upper electrode wiring groove so as to form a second wiring layer, a lower electrode wiring layer and an upper electrode wiring layer.

22. The method according to claim 21, wherein said lower electrode film and said upper electrode film are formed of at least one material selected from the group consisting of TaN, TiN, WN, W—Si—N, Ti—Si—N, and Ta—Si—N.

23. The method according to claim 20, further comprising:
forming an upper electrode wiring hole at the same time that said wiring connection hole and the lower electrode connection hole are formed.

24. A method of manufacturing a semiconductor device, comprising:
forming a first interlayer insulation film on a semiconductor substrate;
forming multiple first wiring grooves in said first interlayer insulation film;
forming multiple first wiring layers by filling each of said first wiring grooves with a metal film;
forming a barrier metal film on said first interlayer insulation film and said first wiring layer;
forming a second interlayer insulation film on said barrier metal film;
forming a wiring connection hole and an electrode connection hole in said second interlayer insulation film, said electrode connection hole reaching said first wiring layer through said barrier metal film;
forming a second wiring groove and an electrode wiring groove in said second interlayer insulation film, said second wiring groove communicating with said wiring connection hole, said electrode wiring groove communicating with said electrode connection hole;
forming a lower electrode film on the surface of said electrode connection film and the bottom face of said electrode wiring groove;
forming a capacitor insulation film comprising a dielectric film on said lower electrode film;
forming an upper electrode film comprising the second barrier metal film on said capacitor insulation film, said lower electrode film, the capacitor insulation film and the upper electrode film composing an MIM-type capacitor; and
filling said wiring connection hole, the second wiring groove, the electrode connection hole and the electrode wiring groove with a metal film.

25. The method according to claim 24, wherein
said wiring connection hole reaches said first wiring layer when said barrier metal film is removed after said MIM-type capacitor is formed.

26. The method according to claim 24, wherein said lower electrode film and said upper electrode film are formed of at least one material selected from the group consisting of TaN, TiN, WN, W—Si—N, Ti—Si—N, and Ta—Si—N.
